(19) United States
(12) Patent Application Publication
(10) Pub. No.: US 2011/0134043 A1
(43) Pub. Date: Jun. 9, 2011

(54) MULTI-STATE INPUT SYSTEM

(76) Inventor: Xing Chen, Beijing (CN)

(21) Appl. No.: 12/531,694

(22) PCT Filed: Aug. 27, 2008
(86) PCT No.: PCT/CN2008/072164

§ 371 Date: Sep. 17, 2009

(51) Int. Cl. G06F 3/02; H03M 11/00

(52) U.S. Cl. 345/168; 341/22

(57) ABSTRACT

A multi-state input system is described. Specifically, one embodiment of the disclosure sets forth a method, which includes the steps of receiving a first input signal, determining a first set of input parameters associated with the first input signal, and executing a predetermined function when the first set of input parameters is identified.

### BACKGROUND

Unless otherwise indicated herein, the approaches described in this section are not prior art to the claims in this application and are not admitted to be prior art by inclusion in this section.

A conventional input device, such as a keyboard, consisting of an arrangement of buttons, or keys, typically serves as an input device to a computing device. Each key press may cause a single symbol to be generated or action affecting the operation of the keyboard itself or the computing device to be performed. Pressing and holding several keys simultaneously or in sequence may lead to the generation of other symbols or the performance of other actions. The program in operation on the computing device may assign functions to keystroke combinations, also referred to as shortcuts.

As a computing device becomes increasingly complex and offers enhanced capabilities, a conventional input device needs to be used in combination with other input devices, such as a mouse, to fully explore and manipulate all the functions supported by such a computing device.

However, as the trend of miniaturizing computing devices continues, mobile phones, PDAs, and other handheld devices, though still packed with advanced graphics and computing capabilities, only have limited space to support input devices, such as small keyboards with far fewer keys. As a result, the ability to navigate and utilize many of the capabilities supported by handheld devices is severely limited.

### BRIEF DESCRIPTION OF THE DRAWINGS

So that the manner in which the above recited features of the disclosure can be understood in detail, a more particular description of the disclosure may be had by reference to embodiments, some of which are illustrated in the drawings. It is to be noted, however, that the drawings illustrate only typical embodiments and are therefore not to be considered limiting of its scope, for the disclosure may admit to other equally effective embodiments.

FIG. 1 is a flow chart illustrating the method steps of processing input signals from a keyboard capable of registering or detecting one or more input parameter(s), according to one embodiment of the disclosure;

FIG. 2A is a flow chart illustrating a process for handling input signals from a keyboard, according to one embodiment of the disclosure;

FIG. 2B is a flow chart illustrating a process for handling successive single-key input signals, according to one embodiment of the disclosure;

FIG. 3 is a conceptual diagram illustrating the processing of a single-key input, according to one embodiment of the disclosure;

FIG. 4 is a conceptual diagram illustrating the processing of successive single-key inputs, according to one embodiment of the disclosure;

FIG. 5 is flow chart illustrating an initialization process for a multi-state input system, according to one or more aspects of the disclosure; and

FIG. 6 is a conceptual system diagram of a multi-state input system configured to implement one or more aspects of the disclosure.

### DETAILED DESCRIPTION

Throughout this disclosure, the term “keyboard” broadly refers to an input device including an arrangement of buttons, or keys. By pressing these keys, input signals representative of data and/or various combinations of symbols, letters, semi-syllabaries, characters, and numerals are generated. A keyboard may be a separate unit or may be incorporated into another device. A keyboard may vary in size. A keyboard may be a physical keyboard or a graphical keyboard on a display screen. In accordance with an embodiment of this disclosure, a “multi-state input system” broadly refers to an input device such as a keyboard capable of detecting one or more input parameter(s), such as different input pressures and also the associated components, to interpret or convert the detected input parameter into an executable function. The following disclosure provides further detail on some illustrative implementations of such features.

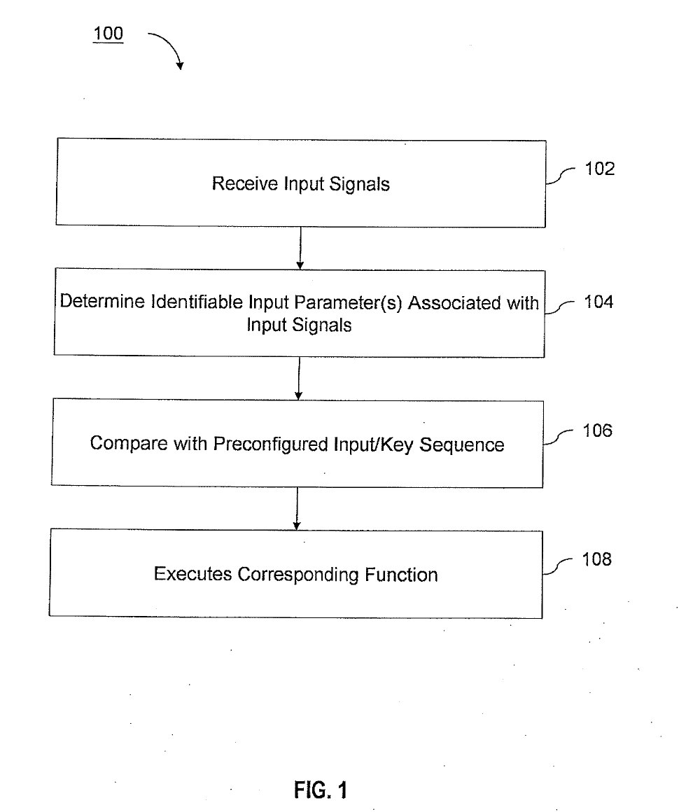

FIG. 1 is a flow chart 100 illustrating the method steps of processing input signals from a keyboard capable of registering or detecting one or more input parameter(s), according to one embodiment of the disclosure. In one implementation, this keyboard is further coupled to a computing device, which is configured to execute one or more software programs. After having received input signals from the keyboard in step 102, the input signals are compared with predetermined stored parameters to determine certain identifiable input parameter(s). “Identifiable input parameters” generally refers to the input data or signals that are identifiable by the multi-state input system and is to be further processed. As an example, suppose the predetermined stored parameters include pressure levels of a key press (e.g., light-pressed or heavy-pressed), time interval between successive key presses (e.g., at least x seconds), time duration of a key press (e.g., at least y seconds), or combinations thereof. So, the identifiable input parameters that may be determined and identified for further processing include, without limitation, a first key press that is considered as either light-pressed or heavy-pressed, the amount of time between this first key press and a subsequent second key press that is at least x seconds apart, and the duration of the first key press that lasts at least y seconds. Additionally, the parameters may be preconfigured, manually modified, or automatically modified according to a usage pattern of the keyboard.

In step 106, the identifiable input parameter(s) is compared with at least one preconfigured input/key sequence. In one implementation, such an input/key sequence may correspond to performing a designated action independent of which software program as discussed above is in use. Alternatively, another input/key sequence may cause a predetermined action to be performed depending on which software program is in use.

If a match is found in step 106, then the multi-state input system executes the function corresponding to the preconfigured key sequence to be performed in step 108. As an example, one input/key sequence may be used to exit any and all software programs. Another input/key sequence may be used to highlight text in a word processing program, but the same input/key sequence may be used to crop images in a graphic editing program. Yet another input/key sequence may only be used in a sound editing program and is non-functional elsewhere.

In one implementation, some of the corresponding functions are associated with displaying certain objects on the display of the computing device. As an example, if the function is to select an icon, the icon may be highlighted on the display. As another example, if the function is to show options, an option menu opens on the display.

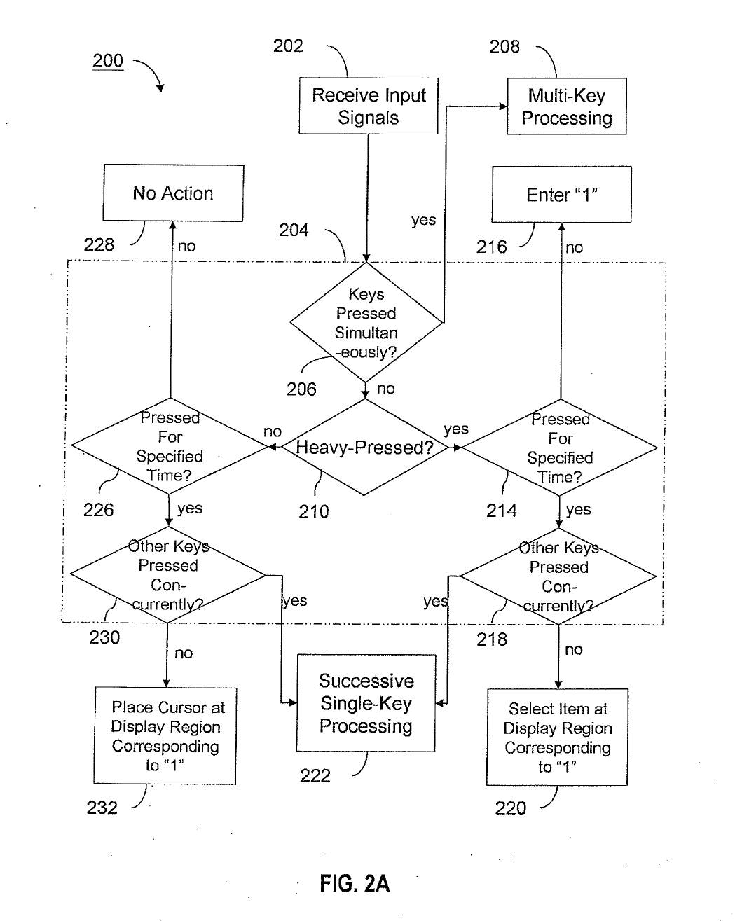

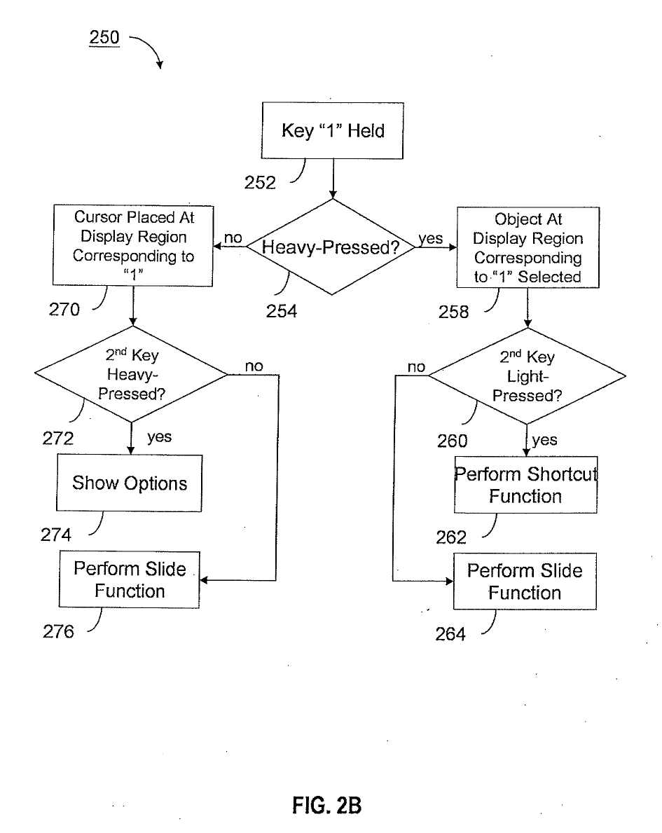

FIG. 2A is a flow chart illustrating a process 200 for handling input signals from a keyboard, according to one embodiment of the disclosure. After having received input signals from the keyboard in step 202, the input signals are compared with predetermined stored parameters to determine identifiable input parameter(s) in step 204. For example, in a representative embodiment, step 204 determines whether keys are pressed simultaneously, whether a key is light-pressed or heavy-pressed, whether a key is pressed for a specified time interval, and whether other keys are pressed concurrently. In another implementation, step 204 can be further divided into multiple independent processes, each of which can be performed in parallel with one another. The sequence of steps shown in step 204 may also vary.

In step 206, the input signals are checked to see if multiple keys are pressed simultaneously. If so, the process 200 proceeds to multi-key processing in step 208. Otherwise, the process 200 continues to process single-key input signals.

In step 210, the single-key input signal is checked to determine the pressure level as applied to the key, for instance whether the key is light-pressed or heavy-pressed. If the key is heavy-pressed, for example, the process 200 checks the length of time a key is pressed, such as whether the key is pressed for at least a specified time in step 214, and whether other keys are pressed concurrently in step 218. If, for example, key “1” is heavy-pressed for at least a specified time, then an item at the display region corresponding to key “1” is selected in step 220. If key “1” is heavy-pressed for less than the specified time, then a value corresponding to key “1” is entered in step 216.

On the other hand, if the single-key input signal is determined in step 210 and identified as light-pressed, the process 200 similarly determines whether the key is pressed for at least a specified time in step 226 and whether other keys are pressed concurrently in step 230. If, for example, key “1” is light-pressed for at least a specified time, a cursor is placed at the display region corresponding to key “1” in step 232. If key “1” is light-pressed for less than the specified time, then no action is performed in step 228. It should be noted that the above discussions are for illustration purposes only. As discussed above, any of the parameters can be optionally modified, predetermined or programmed in advance. For instance, instead of performing no action in step 228 as shown in FIG. 2A, the parameters can be altered so that certain defined action is performed in step 228.

If the process 200 determines that another single key is pressed successively and concurrently in block 204, such input signals are analyzed under successive single-key processing in step 222.

FIG. 2B is a flow chart illustrating a process 250 for handling successive single-key input signals, according to one embodiment of the disclosure. In this example, a first key, key “1,” is held down in step 252 before a second single-key input signal is received. In step 254, the process 250 determines whether the first key is light-pressed or heavy-pressed. If the first key is heavy-pressed, an object at the display region corresponding to key “1” is selected in step 258. If it is light-pressed, a cursor is placed at the display region corresponding to key “1” in step 270.

If the first key is heavy-pressed, then the process 250 determines whether the second key input signal is a light-press in step 260. If so, the second key input signal along with the first heavy-pressed key, which is still being held, causes a shortcut function to be performed in step 262 on the object selected in step 258. On the other hand, if the second key is not light-pressed, then a slide function is to be performed in step 264. For example, the object selected in step 258 may be moved to a new position corresponding to the slide of step 264.

If instead the first key is light-pressed, the process 250 then determines whether the second key input signal is a hard-press in step 272. If so, the second key input signal along with the first light-pressed key, which is still being held, causes a menu of options to be shown in step 274. Otherwise, a slide function is to be performed in step 276. In one example, an area from the cursor placement of step 270 and corresponding to the slide of step 276 is highlighted on the display.

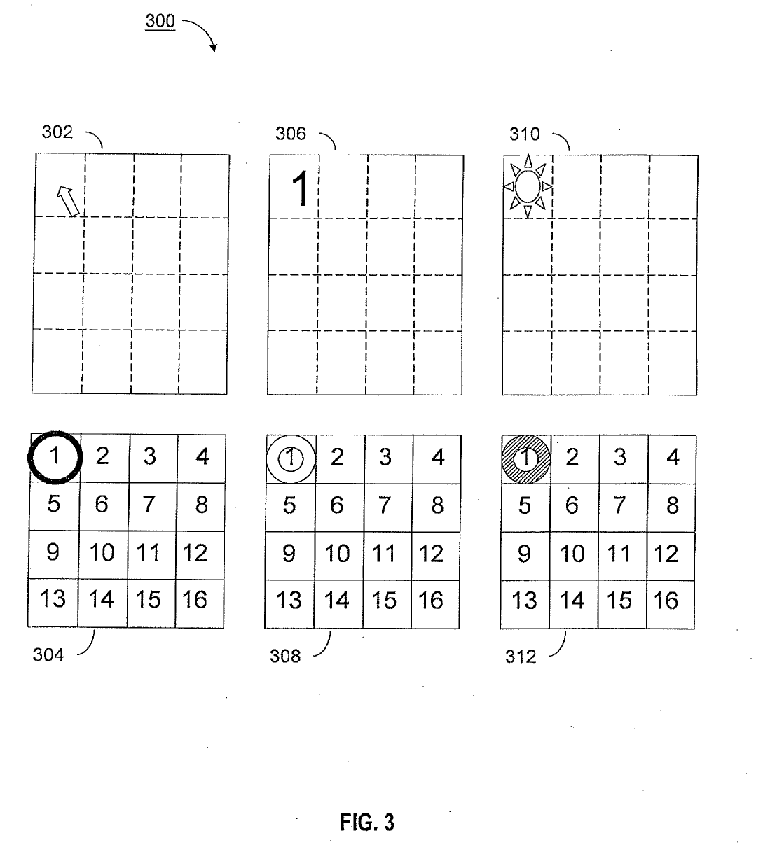

FIG. 3 is a conceptual diagram 300 illustrating the processing of a single-key input, according to one embodiment of the disclosure. Here, the “1” key is pressed in three different ways. On a keyboard 304, the “1” key is light-pressed for a specified time. The keyboard 304 is coupled to a computing device, which includes a display 302. On the display 302, a cursor is shown to be placed at the display region corresponding to the light-pressed “1” key.

On a keyboard 308, the “1” key is instead heavy-pressed, but not for the duration of a specified time. For example, suppose the duration of the specified time is set at 0.5 seconds. The “1” key here is only pressed for 0.2 seconds. Similar to the keyboard 304 discussed above, the keyboard 308 is also coupled to a computing device, which includes a display 306. The numeral “1” is as a result entered into the computing device, and the numeral “1” is also shown on the display 306.

On a keyboard 312, the “1” key is heavy-pressed for the duration of a specified time. Following the example above, suppose the duration of the specified time is again set at 0.5 seconds. The “1” key is pressed for at least 0.5 seconds. On the display 310, an item at the display region corresponding to “1” key is shown to be selected.

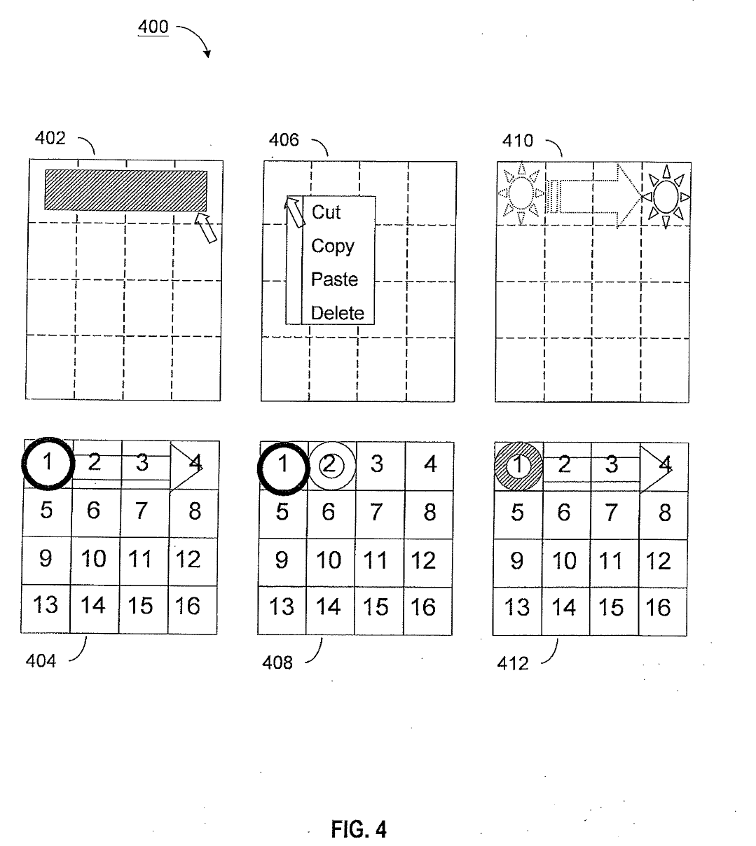

FIG. 4 is a conceptual diagram 400 illustrating the processing of successive single-key inputs, according to one embodiment of the disclosure. In this example, the “1” key is pressed first, followed by at least a second single-key input beginning on the “2” key. On a keyboard 404, the “1” key is light-pressed for a specified time, resulting in a cursor being placed at the display region corresponding to “1” as shown in a display 402. The subsequent successive single-key presses, such as “2-3-4,” cause a slide function to be performed. The display 402 shows the highlighting of the selected area corresponding to the keys “1-2-3-4.”

On a keyboard 408, the “1” key is first light-pressed, again resulting in a cursor being placed at the display region corresponding to “1” as shown in a display 406. The second single-key is heavy-pressed but does not last the duration of the specified time. As discussed above in conjunction with FIG. 2B, a menu of options is shown on the display 406.

On a keyboard 412, the “1” key is first heavy-pressed for the duration of the specified time, resulting in an object at the display region corresponding to “1” on a display 410 to be selected. The subsequent successive single-key presses, such as “2-3-4,” cause a slide function to be performed. The display 410 shows the selected object being moved to the display region corresponding to “4.”

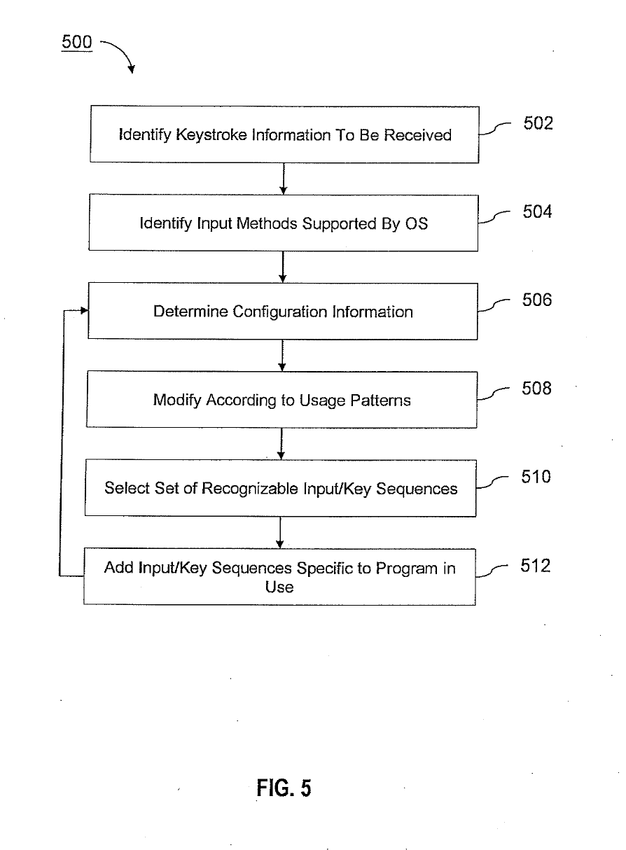

FIG. 5 is flow chart illustrating an initialization process 500 for the multi-state input system, according to one or more aspects of the disclosure. In one implementation, a device driver is used to execute the initialization process 500. Alternatively, a dedicated hardware engine, such as a customized IC, may be configured to execute the initialization process 500. In yet another implementation, a programmable hardware engine, such as a programmable IC, configured with certain software program to execute the initialization process 500.

Using the device driver implementation as an illustration, in step 502, the device driver identifies the type of keystroke information it is likely to receive (e.g., alphanumeric information, semi-syllabary information, and others). In step 504, the input methods supported by the multi-state input system and also the OS of a computing device coupled to the multi-state input system are identified. As an example, suppose the computing device is a mobile device. The device driver may be configured to determine the keyboard layout and also whether the keyboard is capable of registering different pressure inputs.

In step 506, the device driver determines whether there is configuration information associated with the multi-state input system. For example, in this step the device driver may determine whether the parameters as discussed above are defined. In step 508, the configuration information, such as the parameters, can be further modified according to usage patterns. For example, if the initially defined pressure parameters for key presses or time interval parameter for between key presses are inadequate (e.g., rendering the multi-state input system difficult to use), then these parameters can be modified.

In step 510, based on the information retrieved from the steps discussed above, the device driver determines a set of recognizable input/key sequences to access. In one implementation, different sets of recognizable input/key sequences are preconfigured. Optionally, input/key sequences specific to the program in use can be added in step 512. For example, if the program in use is a multi-language word processing program, then the device driver may be configured to include certain input/key sequences, such as key sequences for switching from one language input method to another, that are specific to this word processing program.

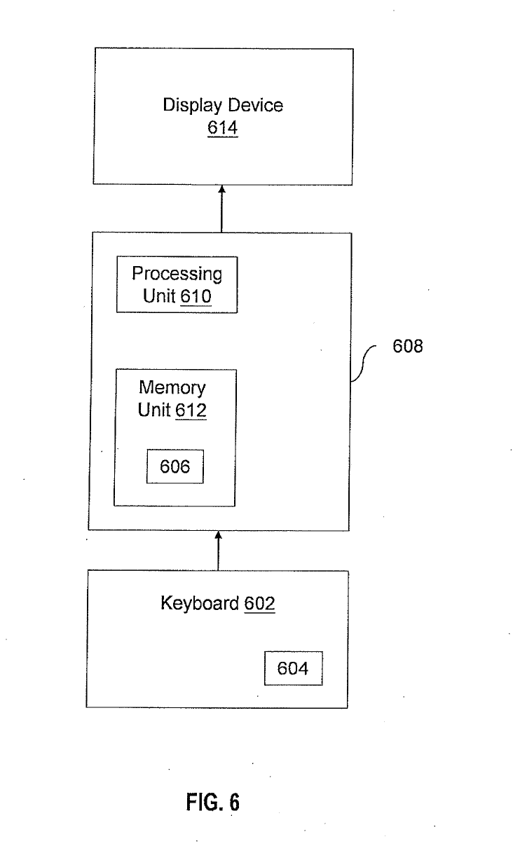

FIG. 6 is a conceptual system diagram of a multi-state input system 600 configured to implement one or more aspects of the disclosure. The multi-state input system 600 includes a keyboard 602 and an input signal interpreter 606. The keyboard 602 includes a pressure sensor 604 capable of capturing state information associated with varying pressures exerted on each key of the keyboard 602. In one implementation, the keyboard 602 is coupled to a computing device 608 either as a physically distinct unit or integrated as a part of the computing device 608. Some examples of the computing device 608 include, without limitation, a desktop computer, server, laptop computer, palm-sized computer, tablet computer, game console, cellular telephone, hand-held device, mobile device, computer based simulator, or the like. The computing device 608 is further coupled to a display device 614.

In one implementation, the input signal interpreter 606 corresponds to computer-readable program instructions that are stored in a memory unit 612. These instructions, when executed by a processing unit 610, causes the processing unit 610 to perform the various processes illustrated and described above.

While the foregoing is directed to embodiments of the disclosure, other and further embodiments of the disclosure may be devised without departing from the basic scope thereof. For example, aspects of the disclosure may be implemented in hardware or software or in a combination of hardware and software. One embodiment of the disclosure may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory devices within a computer such as CD-ROM disks readable by a CD-ROM drive, DVD disks readable by a DVD driver, ROM chips or any type of solid-state non-volatile semiconductor memory) on which information is permanently stored; and (ii) writable storage media (e.g., floppy disks within a diskette drive, hard-disk drive, CD-RW, DVD-RW, solid-state drive, flash memory, or any type of random-access memory) on which alterable information is stored. Such computer-readable storage media, when carrying computer-readable instructions that direct the functions of the disclosure, are embodiments of the disclosure. Therefore, the above examples, embodiments, and drawings should not be deemed to be the only embodiments, and are presented to illustrate the flexibility and advantages of the disclosure as defined by the following claims.

1. A data input method comprising:
receiving a first input signal;
determining a first set of input parameters associated with the first input signal; and
executing a predetermined function when the first set of input parameters is identified.

2. The method of claim 1, wherein the first input signal is generated by pressing a first key on a keyboard.

3. The method of claim 2, further comprising comparing the first set of input parameters with a recognized input sequence, wherein the recognized input sequence corresponds to the predetermined function.

4. The method of claim 3, wherein the recognized input sequence includes first pressure state information associated with the first key.

5. The method of claim 3, wherein the recognized input sequence further includes duration of the first key being pressed.

6. The method of claim 5, wherein the predetermined function to be performed is to highlight a display region on a display device corresponding to the first key.

7. The method of claim 5, wherein the predetermined function to be performed is to select an object in a display region on a display device corresponding to the first key.

8. The method of claim 4, further comprising receiving a second input signal generated by successively pressing a second key on the keyboard.

9. The method of claim 8, wherein the recognized input sequence includes second pressure state information associated with the second key.

10. The method of claim 9, wherein the recognized input sequence includes duration between pressing the first key and pressing the second key.

11. The method of claim 10, wherein the predetermined function to be performed is to highlight a display region on a display device corresponding to a slide movement from the first key to the second key.

12. The method of claim 10, wherein the predetermined function to be performed is specified as a shortcut.

13. The method of claim 10, wherein the predetermined function to be performed is to select and move an object on a display device from a first display region corresponding to the first key to a second display region corresponding to the second key.

14. The method of claim 10, wherein the predetermined function to be performed is to present a menu with selectable options.

15. The method of claim 3, further comprising selecting the recognized input sequence from a plurality of possible input sequences based on a type of the first input signal, an input method supported by an operating system, or configuration information.

16-17. (canceled)

18. A multi-state input system, comprising:
a keyboard capable of registering multiple state information; and
an input signal interpreter, coupled to the keyboard, configured to
receive a first input signal generated by pressing a first key on the keyboard,
determine a first set of input parameters associated with the first input signal, and
execute a predetermined function when the first set of input parameters is identified.

19. The multi-state input system of claim 18, wherein the input signal interpreter is further configured to compare the first set of input parameters with a recognized input sequence, wherein the recognized input sequence corresponds to the predetermined function.

20. The multi-state input system of claim 19, wherein the recognized input sequence includes first pressure state information associated with the first key.

21. The multi-state input system of claim 19, wherein the recognized input sequence further includes duration of the first key being pressed.

22. The multi-state input system of claim 21, wherein the predetermined function is to highlight a display region on a display device corresponding to the first key.

23. The multi-state input system of claim 21, wherein the predetermined function is to select an object in a display region on a display device corresponding to the first key.

24. The multi-state input system of claim 20, wherein the input signal interpreter is further configured to receive a second input signal generated by successively pressing a second key on the keyboard.

25. The multi-state input system of claim 24, wherein the recognized input sequence includes second pressure state information associated with the second key.

26. The multi-state input system of claim 25, wherein the recognized input sequence includes duration between pressing the first key and pressing the second key.

27. The multi-state input system of claim 26, wherein the predetermined function is to highlight a display region on a display device corresponding to a slide movement from the first key to the second key.

28. The multi-state input system of claim 26, wherein the predetermined function is specified as a shortcut.

29. The multi-state input system of claim 26, wherein the predetermined function is to select and move an object on a display device from a first display region corresponding to the first key to a second display region corresponding to the second key.

30. The multi-state input system of claim 26, wherein the predetermined function is to present a menu with selectable options.

31. The multi-state input system of claim 19, wherein the input signal interpreter is configured to select the recognized input sequence from a plurality of possible input sequences based on a type of the first input signal, an input method supported by an operating system for the multi-state input system, or configuration information associated with the multi-state input system.

32. A computer readable medium storing a sequence of program instructions for supporting data input, which when executed by a processing unit in a multi-state input system, causes the processing unit to
receive a first input signal;
determine a first set of input parameters associated with the first input signal; and
execute a predetermined function when the first set of input parameters is identified.

33. The computer readable medium of claim 32, wherein the first input signal is generated by pressing a first key on a keyboard.

34. The computer readable medium of claim 33, further comprising a sequence of program instructions, which when executed by the processing unit, causes the processing unit to compare the first set of input parameters with a recognized input sequence, wherein the recognized input sequence corresponds to the predetermined function.

35. The computer readable medium of claim 34, wherein the recognized input sequence includes first pressure state information associated with the first key.

36. The computer readable medium of claim 34, wherein the recognized input sequence further includes duration of the first key being pressed.

37. The computer readable medium of claim 36, wherein the predetermined function is to highlight a display region on a display device corresponding to the first key.

38. The computer readable medium of claim 36, wherein the predetermined function is to select an object in a display region on a display device corresponding to the first key.

39. The computer readable medium of claim 35, further comprising a sequence of program instructions, which when executed by the processing unit, causes the processing unit to receive a second input signal generated by successively pressing a second key on the keyboard.

40. The computer readable medium of claim 39, wherein the recognized input sequence includes second pressure state information associated with the second key.

41. The computer readable medium of claim 40, wherein the recognized input sequence includes duration between pressing the first key and pressing the second key.

42. The computer readable medium of claim 41, wherein the predetermined function is to highlight a display region on a display device corresponding to a slide movement from the first key to the second key.

43. The computer readable medium of claim 41, wherein the predetermined function is specified as a shortcut.

44. The computer readable medium of claim 41, wherein the predetermined function is to select and move an object on a display device from a first display region corresponding to the first key to a second display region corresponding to the second key.

45. The computer readable medium of claim 41, wherein the predetermined function is to present a menu with selectable options.

46. The computer readable medium of claim 34, further comprising a sequence of program instructions, which when executed by the processing unit, causes the processing unit to select the recognized input sequence from a plurality of possible input sequences based on a type of the first input signal, an input method supported by an operating system for the multi-state input system, or configuration information associated with the multi-state input system.
